(19) United States
(12) Patent Application Publication
(10) Pub. No.: US 2022/0140217 A1
(43) Pub. Date: May 5, 2022

(54) LIGHT EMITTING DIODE STRUCTURE AND METHOD FOR MANUFACTURING THE SAME

(71) Applicant: Raysolve Optoelectronics (Suzhou) Company Limited, Suzhou (CN)

(72) Inventor: Wing Cheung Chong, Hong Kong (CN)

(73) Assignee: Raysolve Optoelectronics (Suzhou) Company Limited, Suzhou (CN)

(21) Appl. No.: 17/469,066

(22) Filed: Sep. 8, 2021

Related U.S. Application Data
(60) Provisional application No. 63/108,307, filed on Oct. 31, 2020.
(60) Provisional application No. 63/108,260, filed on Oct. 30, 2020.

(51) Int. Cl. H01L 33/62; G09G 3/32; H01L 27/15; H01L 33/00

(52) U.S. Cl. CPC H01L 33/62; G09G 3/32; H01L 2933/0066; H01L 33/005; H01L 27/156

(57) ABSTRACT

A LED structure includes a substrate, a LED driving circuit, a plurality of conductive pads, and a first LED set. The LED driving circuit is formed in the substrate, and the LED driving circuit includes a plurality of contacts. The plurality of conductive pads are formed on the LED driving circuit, and each conductive pad of the plurality of conductive pads is disposed on a corresponding contact of the plurality of contacts. The first LED set includes a plurality of LED units disposed on a first conductive pad of the plurality of conductive pads. The plurality of LED units of the first LED set are in electric contact with the corresponding contact through the first conductive pad.

### CROSS-REFERENCE TO RELATED APPLICATION

This application claims the benefit of priority of U.S. Provisional Application No. 63/108,260, filed on Oct. 30, 2020, entitled “Monolithic Integration of Micro- or Nano-sized LEDs,” and U.S. Provisional Application No. 63/108,307, filed on Oct. 31, 2020, entitled “Monolithic integration of Micro- or Nano-sized LEDs,” the content of which are incorporated herein by reference in their entirety.

### TECHNICAL FIELD

The present disclosure relates to a light emitting diode (LED) structure and a method for manufacturing the LED structure, and more particularly, to a micro-sized or nano-sized LED structure and the method for manufacturing the same.

### BACKGROUND

In the recent years, LEDs have become popular in lighting applications. As light sources, LEDs have many advantages including higher light efficiency, lower energy consumption, longer lifetime, smaller size, and faster switching.

Displays having micro-scale LEDs are known as micro-LED. Micro-LED displays have arrays of micro-LEDs forming the individual pixel elements. A pixel may be a minute area of illumination on a display screen, one of many from which an image is composed. In other words, pixels may be small discrete elements that together constitute an image as on a display. Pixels are normally arranged in a. two-dimensional (2D) matrix, and are represented using dots. squares, rectangles, or other shapes. Pixels may be the basic building blocks of a display or digital image and with geometric coordinates.

When manufacturing the micro-LEDs, the LED units are bonded to the driving circuits through a bonding process. The bonding process may align each LED unit with a corresponding contact on the driving circuit to have each LED unit contact the corresponding contact. Alignment is generally fine for large-scaled pixel and low-resolution display. However, as the display resolution increases and the pixel size shrinks, e.g., micro-sized or nano-sized LEDs, there is a significant difficulty in the alignment process. Furthermore, the thermal mismatch between the silicon-based complementary metal-oxide-semiconductor (CMOS) drivers and GaN or AlGaInP based epitaxial layer may further create large misalignment during bonding process at high temperature for small pitch micro-display.

Embodiments of the disclosure address the above problems by providing a LED structure with monolithic integration of micro- or nano-sized LEDs and the method for manufacturing the same, and therefore the difficulties of misalignment during the bonding process of small pitch micro-displays could be overcome.

### SUMMARY

Embodiments of the LED structure and method for forming the LED structure are disclosed herein.

In one example, a LED structure is disclosed. The LED structure includes a substrate, a LED driving circuit, a plurality of conductive pads, and a first LED set, The LED driving circuit is formed in the substrate, and the LED driving circuit includes a plurality of contacts. The plurality of conductive pads are formed on the LED driving circuit, and each conductive pad of the plurality of conductive pads is disposed on a corresponding contact of the plurality of contacts, The first LED set includes a plurality of LED units disposed on a first conductive pad of the plurality of conductive pads. The plurality of LED units of the first LED set are in electric contact with the corresponding contact through the first conductive pad.

In another example, a LED structure is disclosed, The LED structure includes a first semiconductor structure and a second semiconductor structure disposed on the first semiconductor structure. The first semiconductor structure includes a substrate, a LED driving circuit, and a plurality of conductive pads. The LED driving circuit is formed in the substrate, and the LED driving circuit includes a plurality of contacts. The plurality of conductive pads are formed on the LED driving circuit, and each conductive pad of the plurality of conductive pads is disposed on a corresponding contact of the plurality of contacts. The second semiconductor structure includes a plurality of active LED sets and a plurality of dummy LED sets. Each active LED set includes a plurality of active LED units disposed on a corresponding conductive pad. Each dummy LED set comprising a plurality of dummy LED units not disposed on any conductive pad.

In a further example, a method for manufacturing a LED structure is disclosed. A LED driving circuit is formed in a first substrate, and the LED driving circuit includes a plurality of contacts. A first semiconductor layer is formed on a second substrate. A plurality of conductive pads are formed on the plurality of contacts respectively. A plurality of LED units are formed in the first semiconductor layer. The second substrate is bonded to the first substrate, and a first set of LED units among the plurality of LED units is in contact with one conductive pad of the plurality of conductive pads, and a second set of LED units among the plurality of LED units is not in contact with any conductive pad. The second substrate is removed.

### BRIEF DESCRIPTION OF THE DRAWINGS

The accompanying drawings, which are incorporated herein and form a part of the specification, illustrate implementations of the present disclosure and, together with the description, further serve to explain the present disclosure and to enable a person skilled in the pertinent art to make and use the present disclosure.

FIG. 1 illustrates a cross section of an exemplary LED structure, according to some implementations of the present disclosure.

FIG. 2 illustrates a top view of an exemplary LED structure, according to some implementations of the present disclosure.

FIG. 3 illustrates atop view of another exemplary LED structure, according to some implementations of the present disclosure.

FIG. 4 illustrates a cross section of another exemplary LED structure, according to some implementations of the present disclosure.

FIG. 5 illustrates a cross section of a further exemplary LED structure, according to some implementations of the present disclosure.

FIG. 6 illustrates a cross section of a further exemplary LED structure, according to some implementations of the present disclosure.

FIG. 7 illustrates a cross section of a further exemplary LED structure, according to some implementations of the present disclosure.

FIGS. 8-12 illustrate cross sections of an exemplary LED structure at different stages of a manufacturing process of the LED structure, according to some implementations of the present disclosure.

FIG. 13 is a flowchart of an exemplary method for manufacturing a LED structure, according to some implementations of the present disclosure.

Implementations of the present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and. modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,”or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered. surface. A substrate can be a layer, can include one or more layers therein, and/or can have one or more layers thereupon, thereabove, and/or therebelow. A layer can include multiple layers. For example, a semiconductor layer can include one or more doped or undoped semiconductor layers and may have the same or different materials.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, silicon carbide, gallium nitride, germanium, gallium arsenide, indium phosphide, etc. Alternatively, the substrate can be made from an electrically non-conductive material, such as a glass, a. plastic, or a sapphire wafer. Further alternatively, the substrate can have semiconductor devices or circuits formed therein.

As used herein, the term “micro” LED, “micro” p-n diode or “micro” device refers to the descriptive size of certain devices or structures according to implementations of the invention. As used herein, the terms “micro” devices or structures are meant to refer to the scale of 0.1 to 100 μm. However, it is to be appreciated that implementations of the present invention are not necessarily so limited, and that certain aspects of the implementations may be applicable to larger, and possibly smaller size scales.

Implementations of the present disclosure describe a LED structure or a micro-LED structure and a method for manufacturing the structure. For manufacturing a micro-LED display, multiple LED units or multiple active LED units might be integrally combined to form one pixel of the display. The multiple active LED units forming one pixel might be controlled by the same pixel driver or different pixel drivers based on various designs. To integrally bond multiple active LED units to the pixel driver, one or more contacts may be exposed on the driving circuit to electrically contact the active LED units.

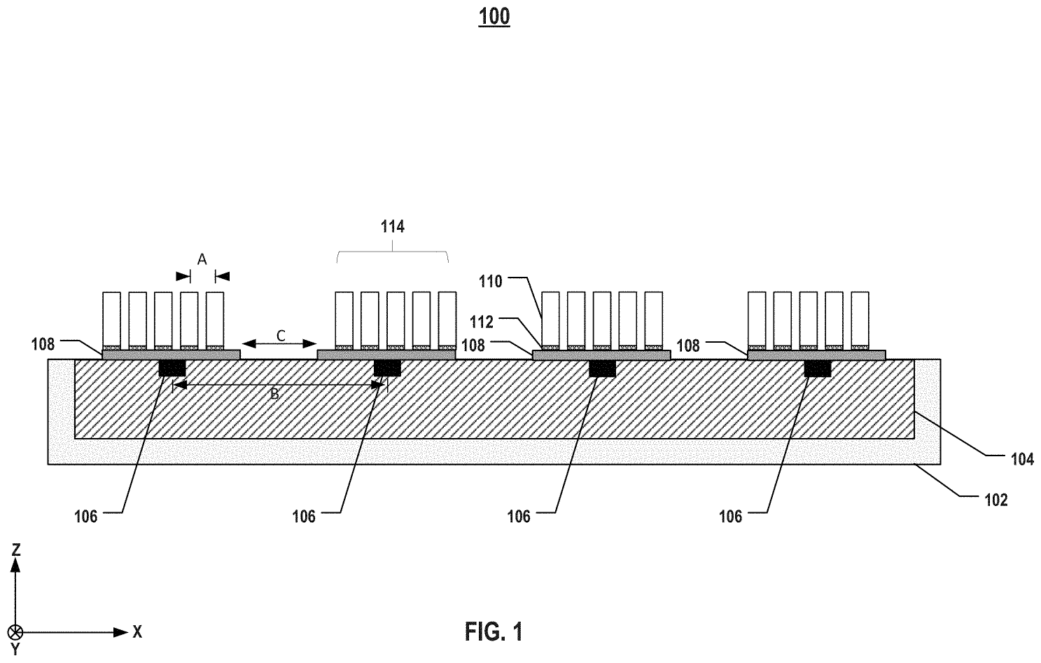

FIG. 1 illustrates a cross section of an exemplary LED structure 100, according to some implementations of the present disclosure, As shown in FIG. 1, LED structure 100 includes a substrate 102, and a LED driving circuit 104 formed in substrate 102.

Substrate 102 may include a semiconductor material, such as silicon, silicon carbide, gallium nitride, germanium, gallium arsenide, or indium phosphide, In some implementations, substrate 102 may be made from an electrically non-conductive material, such as a glass, a plastic or a sapphire wafer. In some implementations, substrate 102 may have one or more LED driving circuit 104 formed therein to control the operations of the display, and substrate 102 may be CMOS backplane or TFT glass substrate.

LED driving circuit 104 provides the electronic signals to a plurality of LED units 110 to control the luminance, In some implementations, LED driving circuit 104 may include an active matrix driving circuit, in which each LED set 114 corresponds to an independent driver. In some implementations, LED driving circuit 104 may include a passive matrix driving circuit, in which the LED sets 114 are aligned in an array and are connected to the data lines and the scan lines driven by LED driving circuit 104.

In some implementations, LED driving circuit 104 may include a plurality of contacts 106. In some implementations, each contact 106 corresponds to one LED set 114, and each LED set 114 includes a plurality of LED units 110, as shown in FIG. 1. In some implementations, a plurality of conductive pads 108 are formed on LED driving circuit 104, and each conductive pad 108 corresponds to one contact 106. In some implementations, conductive pad 108 is a layer of an adhesive material formed on LED driving circuit 104 to bond LED sets 114 with LED driving circuit 104. In some implementations, conductive pad 108 may include a conductive material, such as metal or metal alloy. For example, conductive pad 108 is a metal pad formed on LED driving circuit 104 to bond LED sets 114 with LED driving circuit 104. In some implementations, conductive pad 108 may include Au, Sn, In, Cu, Ti, their alloys, or other suitable materials, it is understood that the descriptions of the material of conductive pad 108 are merely illustrative and are not limiting, and those skilled in the art can make changes according to requirements, all of which are within the scope of the present application.

The plurality of LED units 110 of one LED set 114 are bonded on one conductive pad 108, and therefore the plurality of LED units 110 of one LED set 114 are controlled by LED driving circuit 104 through the same contact 106. In other words, each contact 106 may control multiple LED units 110 bonded on the corresponding conductive pad 108 simultaneously, and those LED units 110 bonded on the same conductive pad 108 may be turned on off by LED driving circuit 104 through the same contact 106 simultaneously to form one pixel point.

In some implementations, as shown in FIG. 1, two adjacent LED units 110 in the same LED set 114 may be separated on conductive pad 108 by a width A. In sonic implementations, as shown in FIG. 1, two adjacent contacts 106 are formed apart a distance B in LED driving circuit 104. In some implementations, as shown in FIG. 1, two adjacent conductive pads 108 are separated by a gap having a distance C on LED driving circuit 104. In some implementations, distance C between two adjacent conductive pads 108 may prevent the electrical short circuit of adjacent LED sets 114, and distance C is larger than width A but smaller than distance B. Because LED unit 110 is a micro-scaled or a nano-scaled LED unit, the width A may be much smaller than the distance B or the distance C. A plurality of LED units 110 may be bonded on the same conductive pad 108 during the manufacturing process. For example, when LED unit 110 is a micro-scaled LED (micro-LED), the width of LED unit 110 may be between 1 and 100 μm. For another example, when LED unit 110 is a nano-scaled LED (nano-LED), the width of LED unit 110 may be between 10 nm and 1000 nm. The size of conductive pad 108 may be micro-scaled or milli-scaled, Hence, during the bonding process, multiple LED units 110 can be bonded on one conductive pad 108.

Each LED unit 110 may include an anode and a cathode, and the anode of each LED unit 110 may be bonded to conductive pad 108 through a conductive layer 112, and the anode of each LED unit 110 may be in electric contact with conductive pad 108 through conductive layer 112. In some implementations, the cathodes of the plurality of LED units 110 of one LED set 114 may be in electric contact with each other. In some implementations, the cathodes of the plurality of LED units 110 of the plurality of LED sets 114 may be in electric contact with each other.

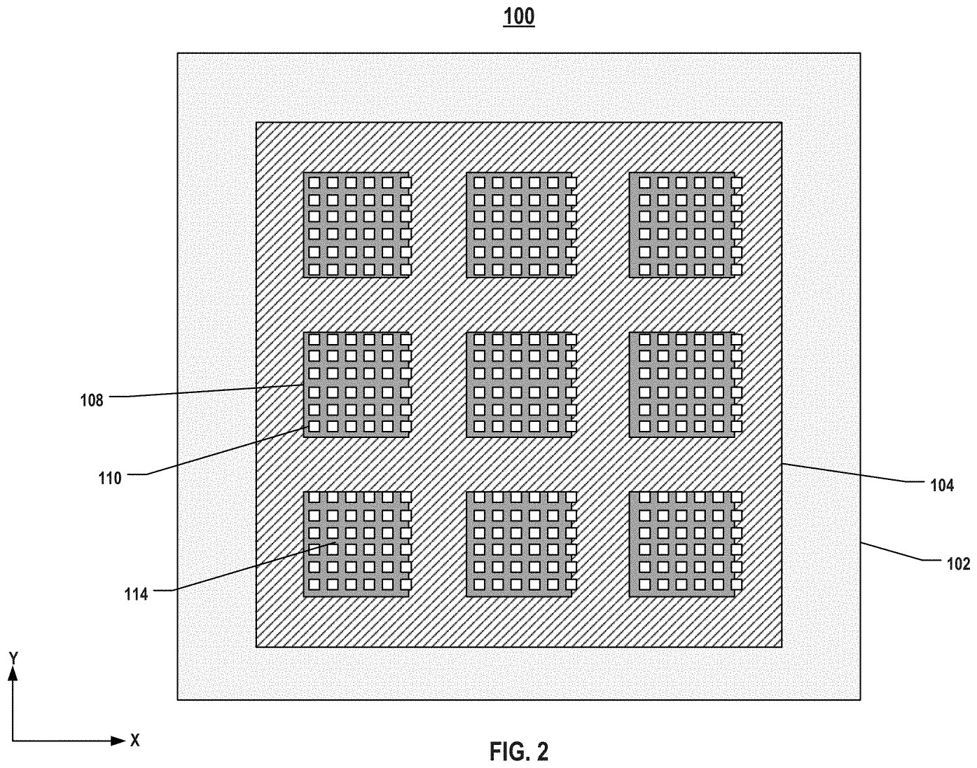

FIG. 2 illustrates a top view of LED structure 100, according to some implementations of the present disclosure. As shown in FIG. 2, each LED set 114, for example, includes 6×6 LED units 110. which are misaligned to conductive pad 108 in x-direction or in y-direction. In other words, the center of each LED set 114 is not aligned to the center of corresponding conductive pad 108. In some implementations, as shown in FIG. 2, some LED units 110 located on edge of the LED set 114 may exceed the boundary of conductive pad 108. Because each LED set 114 may include multiple LED units 110, even when some misalignment occurs during the bonding process, most LED units 110 may be still bonded on and in electric contact with conductive pad 108. Those bonded. LED units 110 can be turned on/off by LED driving circuit through contacts 106 and conductive pads 108 despite the un-bonded LED units cannot. The LED units bonded within the boundary of each conductive pad will keep the corresponding pixel point functional. Therefore, the misalignment within a certain range will not cause noticeable defect of the pixel points.

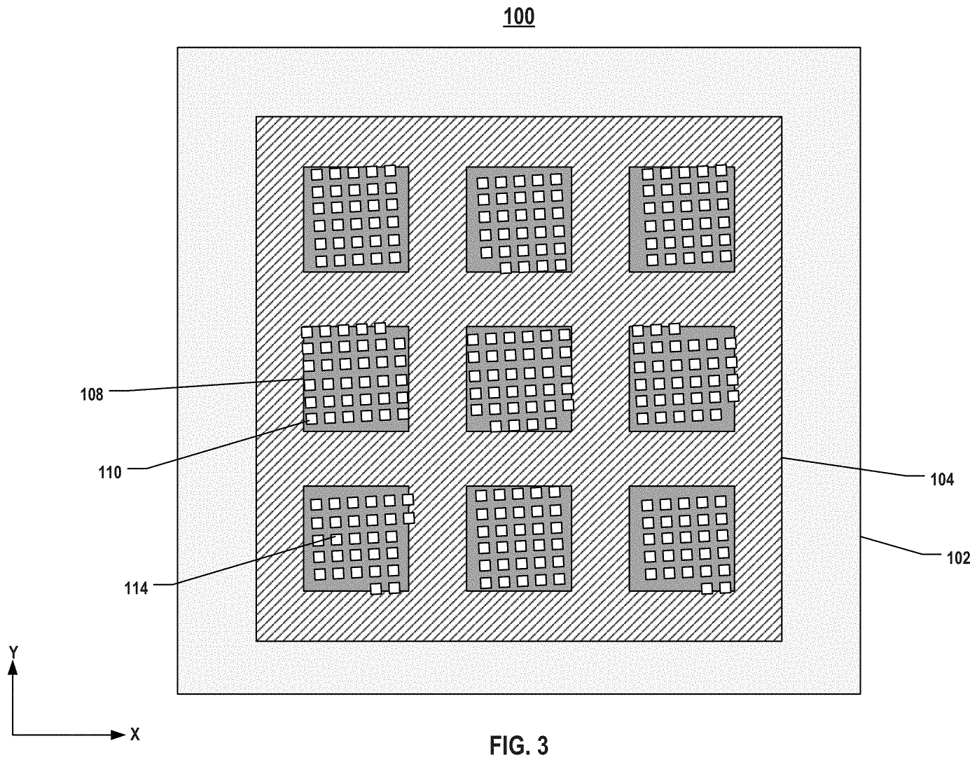

FIG. 3 illustrates another top view of LED structure 100, according to some implementations of the present disclosure. As shown in FIG. 3, LED sets 114 are not only misaligned to conductive pad 108 in x-direction or in y-direction but also have a rotation misalignment. In some implementations, as shown in FIG. 3, some LED units 110 located on edge of the LED set 114 may exceed the boundary of conductive pad 108 and have a certain intersection angle with the edge of conductive pad 108. Because each LED set 114 may include multiple LED units 110, when misalignment of the bonding process, most LED units 110 may be still bonded on and in electric contact with conductive pad 108. Even though some LED units may not function because they are not correctly bonded to conductive pad 108, those bonded LED units 110 can be still turned on/off by LED driving circuit through contacts 106 and conductive pads 108. Therefore, the misalignment or rotation within a certain range will not cause noticeable defect of the pixel points.

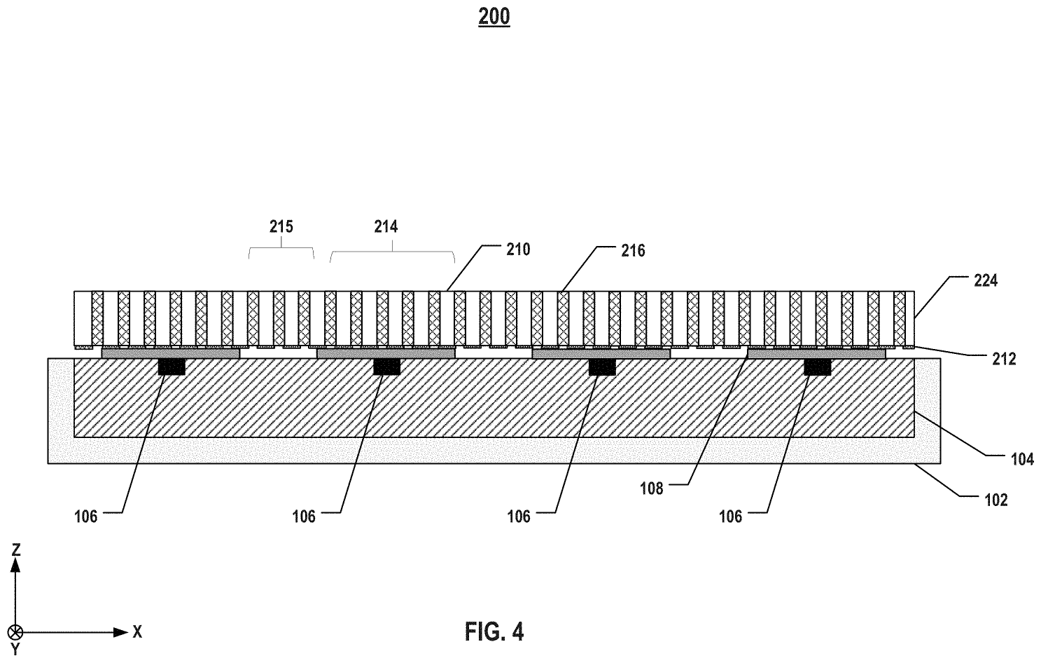

FIG. 4 illustrates a cross section of another exemplary LED structure 200, according to some implementations of the present disclosure. As shown in FIG. 4, LED structure 200 includes substrate 102, and LED driving circuit 104 formed in substrate 102. The materials, structures, and manufacturing processes of substrate 102 and/or LED driving circuit 104 of LED structure 200 may be similar to substrate 102 and/or LED driving circuit 104 of LED structure 100. As shown in FIG. 4, a LED layer 224 is bonded on LED driving circuit 104. The major difference between LED structure 100 and LED structure 200 is that LED units 110 of LED structure 100 are separated by a gap, which may be formed by the etch operation, and LED units 210 of LED structure 200 are separated by an isolation material 216, which may be formed through implantation operation.

LED layer 224 may include a plurality of LED sets 214, and a plurality of LED sets 215. Each LED set 214 may include a plurality of LED units 210 in electric contact with conductive pad 108 (also referred to as “active LED units 210”), and each LED set 215 may include a plurality of dummy LED units not in contact with any conductive pad. LED driving circuit 104 provides the electronic signals to a plurality of LED units 210 to control the luminance. In some implementations, LED driving circuit 104 may include an active matrix driving circuit, in which each LED set 214 corresponds to an independent driver. In some implementations, LED driving circuit 104 may include a passive matrix driving circuit, in which the LED sets 214 are aligned in an array and are connected to the data lines and the scan lines driven by LED driving circuit 104.

In some implementations, LED driving circuit 104 may include a plurality of contacts 106. In some implementations, each contact 106 corresponds to one LED set 214, and each LED set 214 includes a plurality of LED units 210. as shown in FIG. 4. In some implementations, a plurality of conductive pads 108 are formed on LED driving circuit 104, and each conductive pad 108 corresponds to one contact 106. In some implementations, conductive pad 108 is a layer of an adhesive material formed on LED driving circuit 104 to bond LED sets 214 with LED driving circuit 104, In some implementations, conductive pad. 108 is a metal pad formed on LED driving circuit 104 to bond LED sets 214 with LED driving circuit 104. In some implementations, conductive pad 108 may include a conductive material, such as metal or metal alloy. In some implementations, conductive pad 108 may include Au, Sn, In, Cu, Ti, their alloys, or other suitable materials. It is understood that the descriptions of the material of conductive pad 108 are merely illustrative and are not limiting, and those skilled in the art can make changes according to requirements, all of which are within the scope of the present application.

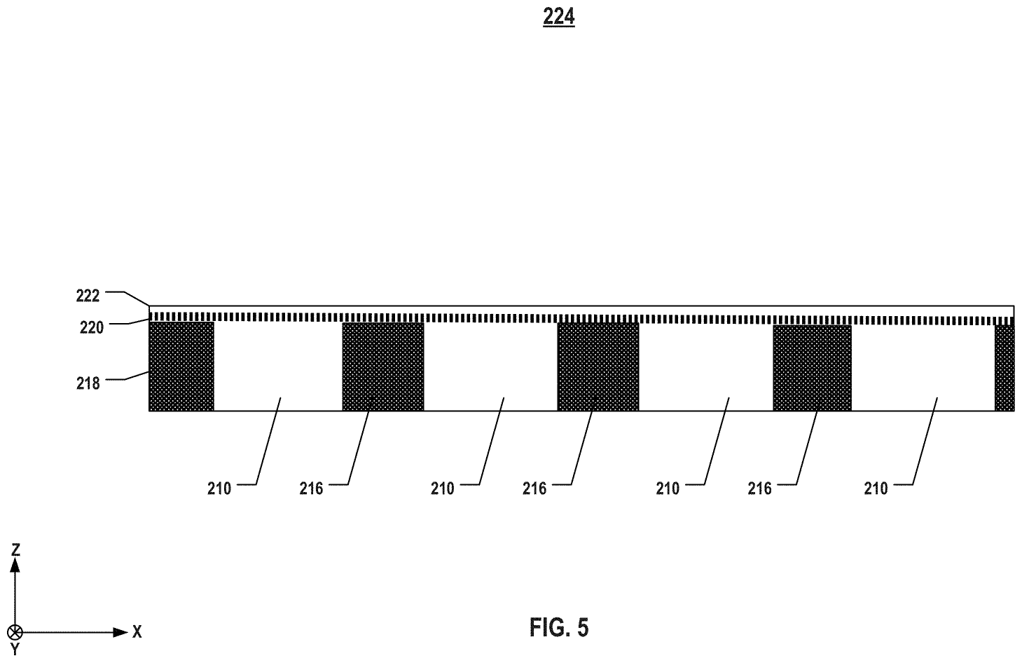

FIG. 5 illustrates a cross section of LED layer 224, according to some implementations of the present disclosure. In some implementations, LED layer 224 includes a first doping semiconductor layer 218, a multiple quantum well (MQW) layer 220 disposed on first doping semiconductor layer 218, and a second doping semiconductor layer 222 disposed on MQW layer 220. In some implementations, first doping semiconductor layer 218 and second doping semiconductor layer 222 may include one or more layers formed with II-VI materials, such as ZnSe or ZnO, or III-V nitride materials, such as GaN, MN, InN, InGaN, GaP, AlInGaP, AlGaAs, and their alloys.

In some implementations, first doping semiconductor layer 218 may be a p-type semiconductor layer and forms an anode of LED unit 210. In some implementations, second doping semiconductor layer 222 may be a n-type semiconductor layer and form a cathode of LED unit 210. In some implementations, first doping semiconductor layer 218 may include p-type GaN. In some implementations, first doping semiconductor layer 218 may he formed by doping magnesium (Mg) in GaN. In some implementations, first doping semiconductor layer 218 may include p-type InGaN. In some implementations, first doping semiconductor layer 218 may include p-type AlInGaP. In some implementations, second doping semiconductor layer 222 may include n-type GaN. In some implementations, second doping semiconductor layer 222 may include n-type InGaN. In some implementations, second doping semiconductor layer 222 may include n-type AlinGaP. LED layer 224 further include MQW layer 220 formed between first doping semiconductor layer 218 and second doping semiconductor layer 222. MQW layer 220 is the active region of LED unit 210.

The adjacent LED units 210 are separated by isolation material 216. In some implementations, isolation material 216 may be formed by implanting ion materials in first doping semiconductor layer 218. In some implementations, isolation material 216 may be formed by implanting H⁺, He⁺, N⁺, O⁺, F⁺, Mg⁺, Si⁺ or Ar⁺ ions in first doping semiconductor layer 218. In some implementations, first doping semiconductor layers 218 may be implanted with one or more ion materials to form isolation material 216. Isolation material 216 has the physical properties of electrical insulation. By implanting an ion material in a defined area of first doping semiconductor layer 218, the material of first doping semiconductor layers 218 in the defined area may be transformed to isolation material 216, which electrically isolates first doping semiconductor layers 218 from each other.

Each LED unit 210 may include an anode and a cathode, and the anode of each LED unit 210 may be bonded to conductive pad 108 through a conductive layer 212, and the anode of each LED unit 210 may be in electric contact with conductive pad 108 through conductive layer 212. In some implementations, the cathodes of the plurality of LED units 210 of one LED set 214 may be in electric contact with each other. In some implementations, the cathodes of the plurality of LED units 210 of the plurality of LED sets 214 may be in electric contact with each other,

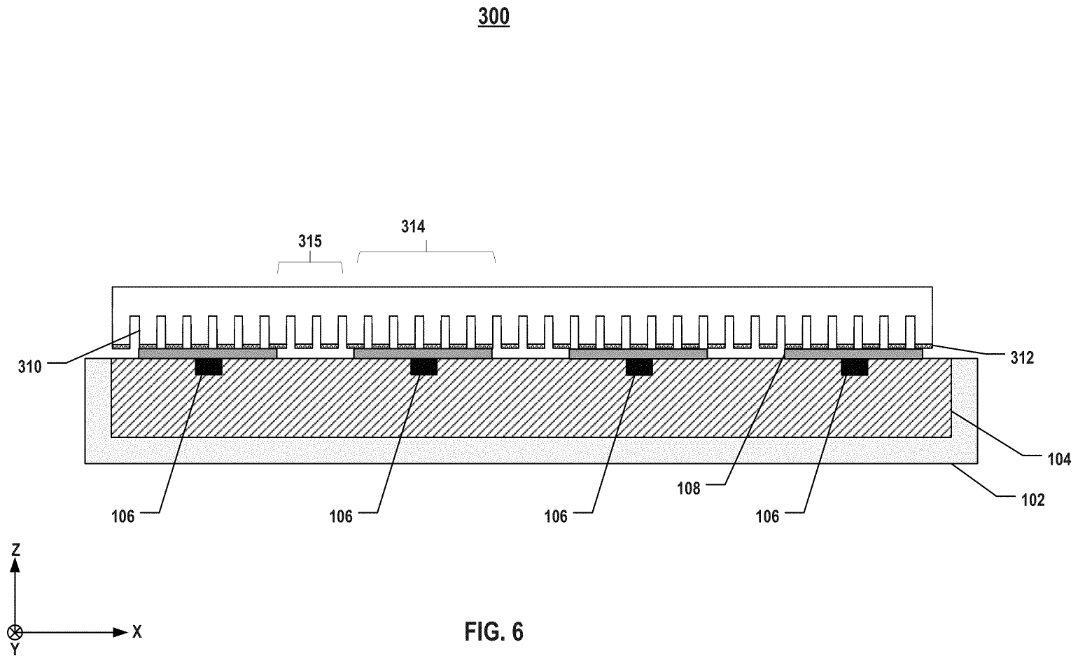

FIG. 6 illustrates a cross section of a further exemplary LED structure 300. according to some implementations of the present disclosure. As shown in FIG. 6, LED structure 300 includes substrate 102, and LED driving circuit 104 formed in substrate 102, The materials, structures, and manufacturing processes of substrate 102 and/or LED driving circuit 104 of LED structure 300 may be similar to substrate 102 and/or LED driving circuit 104 of LED structure 100. As shown in FIG. 6, a plurality of LED sets 314 are bonded on LED driving circuit 104. A plurality of LED sets 315 may include a plurality of dummy LED units not in contact with any conductive pad.

Each LED set 314 may include a plurality of LED units 310. LED structure 300 may be similar to LED structure 100 in FIG. 1, but LED units 310 of LED structure 300 are not fully divided with each other during the etch operation.

As shown in FIG. 6, the bottom ends of LED units 310 are separated and are bonded to contacts 106 through conductive pads 108 and conductive layer 312. The upper ends of LED units 310 are physically connected together. In some implementations, the connected portion of the LED units 310 may be a doped semiconductor layer of each LED unit 310 that forms the cathode. In some implementations, the connected portion of the LED units 310 may be a thinned substrate the supports LED units during the manufacturing process or the etch operation. A portion of the plurality of LED units 310 is boned to conductive pads 108, and. another portion of the plurality of LED units 310 is not. The bonded portion of the plurality of LED units 310 may be controlled by LED driving circuit 104.

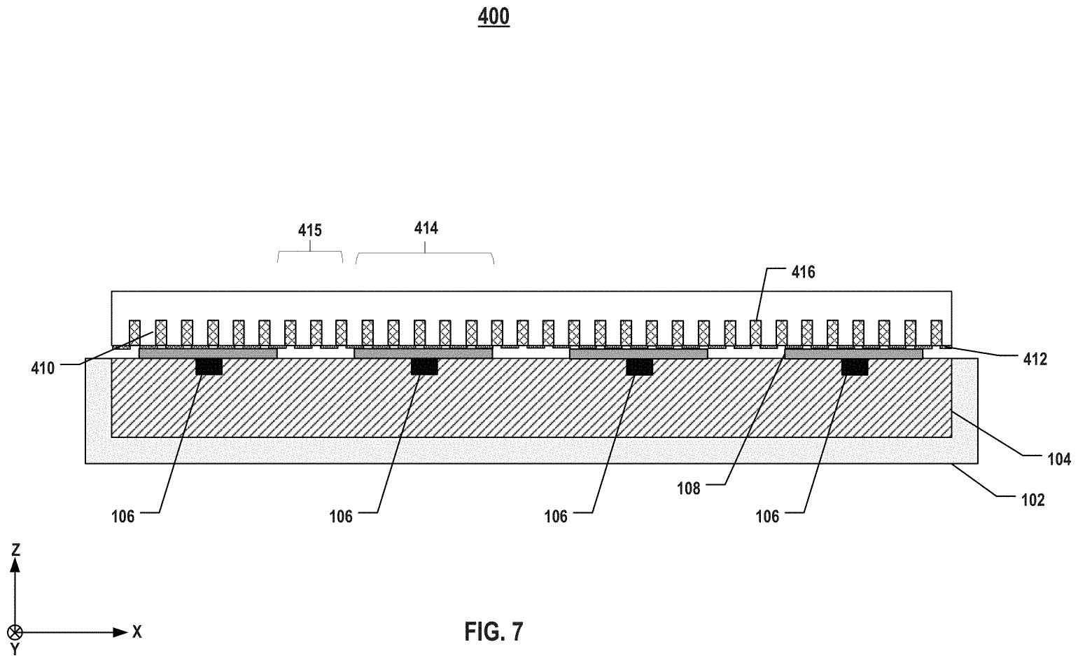

FIG. 7 illustrates a cross section of a further exemplary LED structure 400, according to some implementations of the present disclosure. LED structure 400 may be similar to LED structure 300, but LED units 310 of LED structure 300 are separated by a gap, which may be formed by the etch operation, and LED units 410 of LED structure 400 are separated by an isolation material 416, which may be formed through implantation operation.

As shown in FIG. 7, LED structure 400 includes substrate 102, and LED driving circuit 104 formed in substrate 102. The materials, structures, and manufacturing processes of substrate 102 and/or LED driving circuit 104 of LED structure 400 may be similar to substrate 102 and/or LED driving circuit 104 of LED structure 100. Each LED set 414 may include a plurality of LED units 410 (active LED units) in electric contact with the conductive pad. A plurality of LED sets 415 may include a plurality of dummy LED units not in contact with any conductive pad. LED structure 400 may be similar to LED structure 200 in FIG. 4, but LED units 410 of LED structure 400 are not fully divided or isolated with each other during the isolation operation.

The bottom ends of LED units 310 are isolated by an isolation material 416 and are bonded to contacts 106 through conductive pads 108 and conductive layer 412. The materials, structures, and/or the manufacturing processes of isolation material 416 may be similar to the materials, structures, and/or the manufacturing processes of isolation material 216 in FIG. 4 and FIG. 5. The upper ends of LED units 410 are physically connected together. In some implementations, the connected portion of the LED units 410 may be a doped semiconductor layer of each LED unit 410 that forms the cathode. In some implementations, the connected portion of the LED units 410 may be a thinned substrate the supports LED units during the manufacturing process or the implantation operation. A portion of the plurality of LED units 410 is boned to conductive pads 108, and another portion of the plurality of LED units 410 is not. The bonded portion of the plurality of LED units 410 may be controlled by LED driving circuit 104.

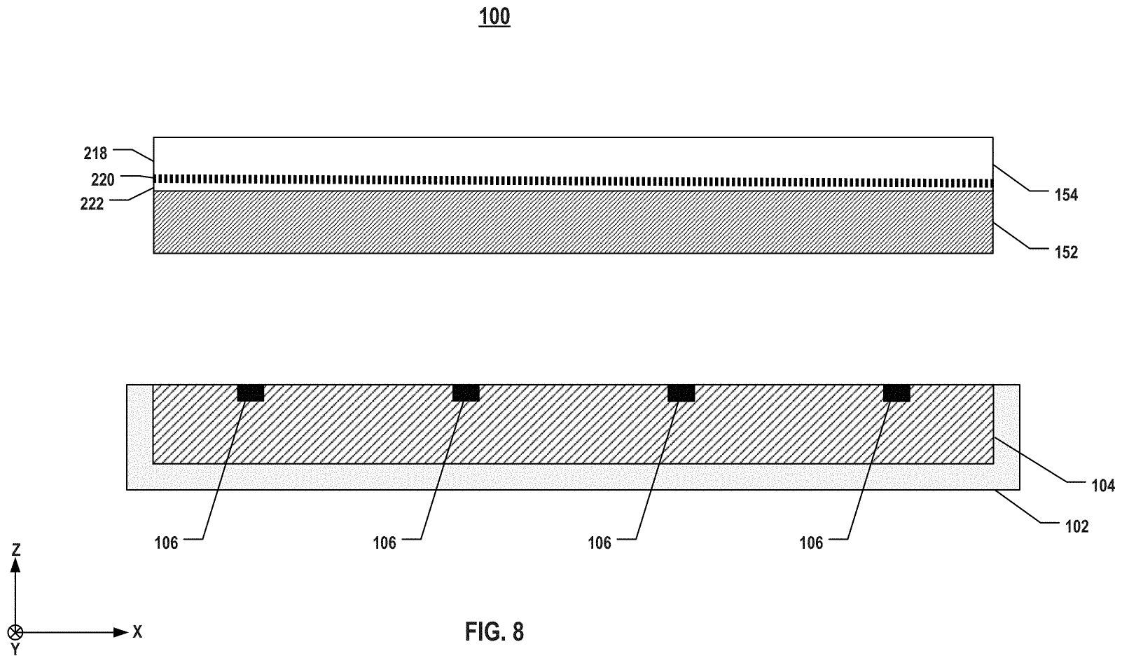

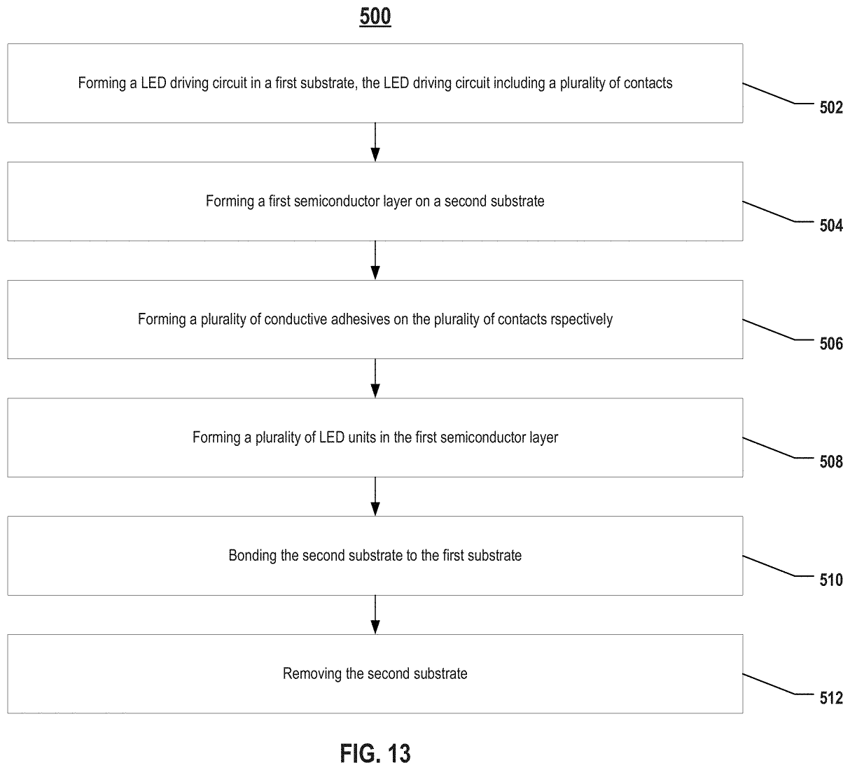

FIGS. 8-12 illustrate cross sections of LED structure 100 at different stages of a manufacturing process of the LED structure, according to some implementations of the present disclosure. FIG. 13 is a flowchart of an exemplary method 500 for manufacturing LED structure 100, according to some implementations of the present disclosure. For the purpose of better describing the present disclosure, the cross sections of LED structure 100 in FIGS. 8-12, and the flowchart of method 500 in FIG. 13, will be described together. It is understood that the operations shown in method 500 are not exhaustive and that other operations may be performed as well before, after, or between any of the illustrated operations. Further, some of the operations may be performed simultaneously, or in a different order than shown in FIGS. 8-12 and FIG. 13.

As shown in FIG. 8 and operation 502 of FIG. 13, LED driving circuit 104 is formed in substrate 102, and LED driving circuit 104 includes a plurality of contacts 106. For example, LED driving circuit 104 may include CMOS devices manufactured on a silicon wafer and some wafer-level packaging layers or fan-out structures are stacked on the CMOS devices to form contacts 106. For another example, LED driving circuit 104 may include TFTs manufactured on a glass substrate and sonic water-level packaging layers or fan-out structures are stacked on the TFTs to form contacts 106.

As shown in FIG. 8 and operation 504 of FIG. 13, a semiconductor layer 154 is formed on a substrate 152. Semiconductor layer 154 may include first doping semiconductor layer 218, MQW layer 220, and second doping semiconductor layer 222.

In some implementations, substrate 102 or substrate 152 may include a semiconductor material, such as silicon, silicon carbide, gallium nitride, germanium, gallium arsenide, indium phosphide. In some implementations, substrate 102 or substrate 152 may be made from an electrically non-conductive material, such as a glass, a plastic or a sapphire wafer. In some implementations, substrate 102 may have driving circuits formed therein, and substrate 102 may include a CMOS backplane or TFT glass substrate. In some implementations, first doping semiconductor layer 218 and second doping semiconductor layer 222 may include one or more layers based on II-VI materials, such as ZnSe or ZnO, or nitride materials, such as GaN, AIN, InN, InGaN, GaP, AlInGaP, AlGaAs, and their alloys. In some implementations, first doping semiconductor layer 218 may include a p-type semiconductor layer, and second doping semiconductor layer 222 may include a n-type semiconductor layer.

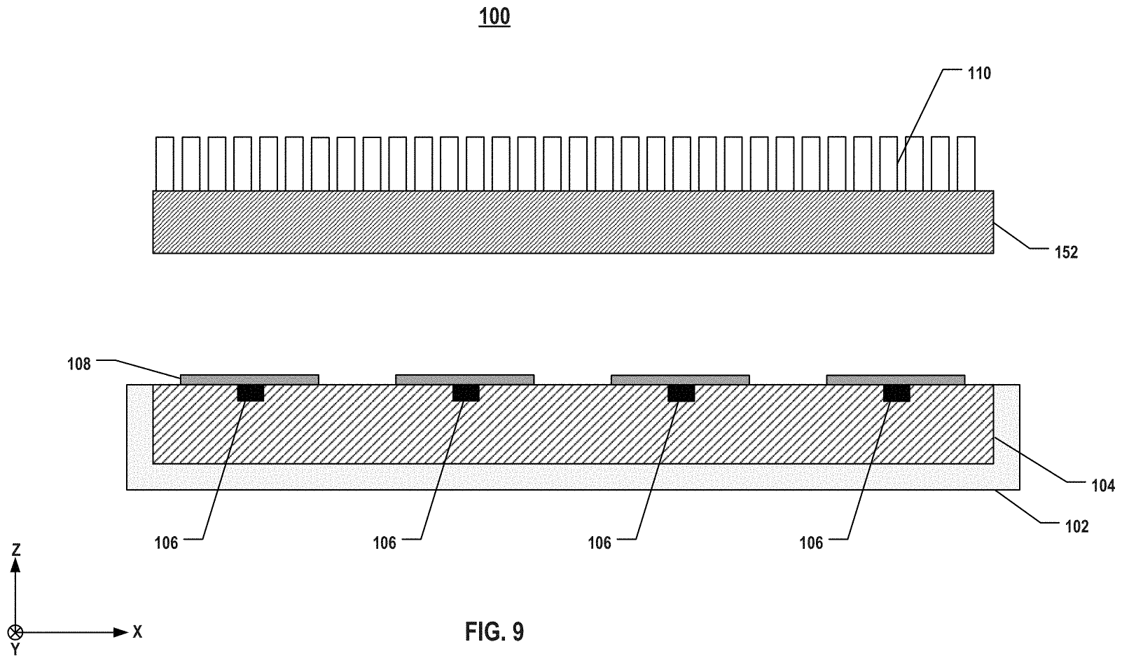

As shown in FIG. 9 and operation 506 of FIG. 13, a plurality of conductive pads 108 are formed on the plurality of contacts 106 respectively, In some implementations, conductive pad 108 may include Au, Sn, In, Cu, Ti, their alloys, or other suitable materials. It is understood that the descriptions of the material of conductive pad 108 are merely illustrative and are not limiting, and those skilled in the art can make changes according to requirements, all of which are within the scope of the present application.

As shown in FIG. 9 and operation 508 of FIG. 13, a plurality of LED units 110 are formed in semiconductor layer 154. In some implementations, the formation of LED units 110 may include the etch operation to separate LED units 110. In some implementations, semiconductor layer 154, including first doping semiconductor layer 218, MQW layer 220, and second doping semiconductor layer 222, is etched in the etch operation to form the gap. In some implementations, only first doping semiconductor layer 218, e.g., p-type semiconductor layer, is etched in the etch operation.

In some implementations, the formation of LED units 110 may include the implantation operation to form an isolation material to separate LED units 110. In some implementations, semiconductor layer 154, including first doping semiconductor layer 218, MQW layer 220, and second doping semiconductor layer 222, is implanted in the implantation operation to form the isolation material. In some implementations, only first doping semiconductor layer 218, e.g., p-type semiconductor layer, is implanted in the implantation operation.

It is understood that the descriptions of the formation of LED units 110 or the process of separation or isolation of LED units are merely illustrative and are not limiting, and those skilled in the art can make changes according to requirements, all of which are within the scope of the present application.

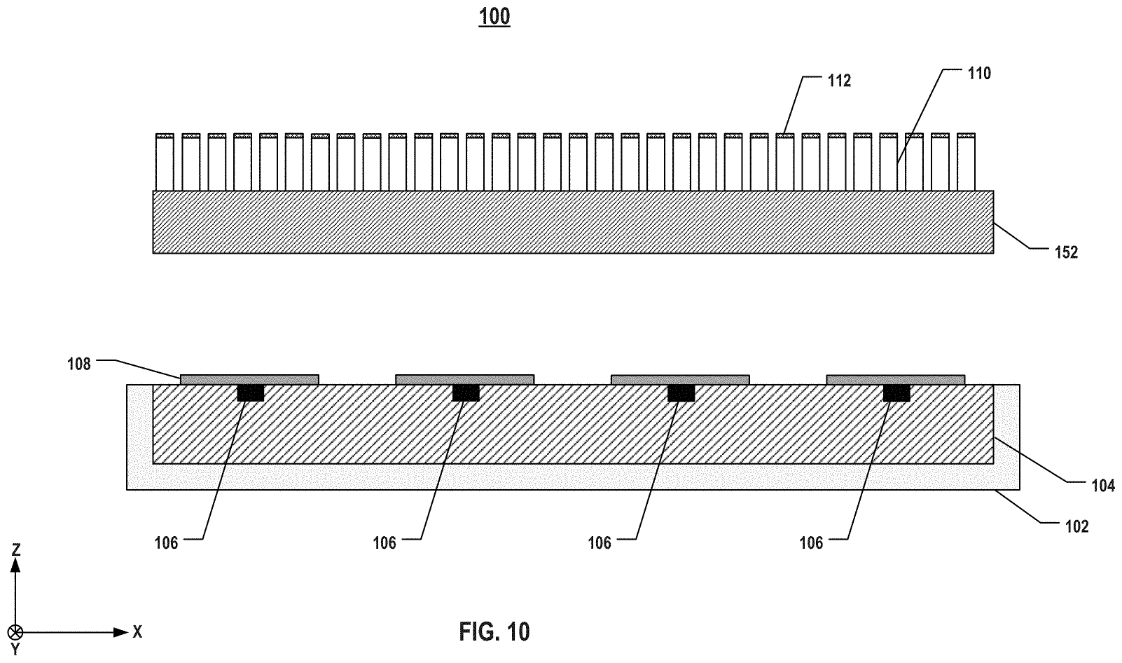

As shown in FIG. 10, conductive layer 112 is then formed on each LED unit 110. In some implementations, conductive layer 112 may be formed on semiconductor layer 154 before operation 508, and conductive layer 112 may be etched with semiconductor layer 154 to form LED units 110. In some implementations, conductive layer 112 may be formed on semiconductor layer 154 after operation 508, and conductive layer 112 may be coated on one end of each LED unit 110.

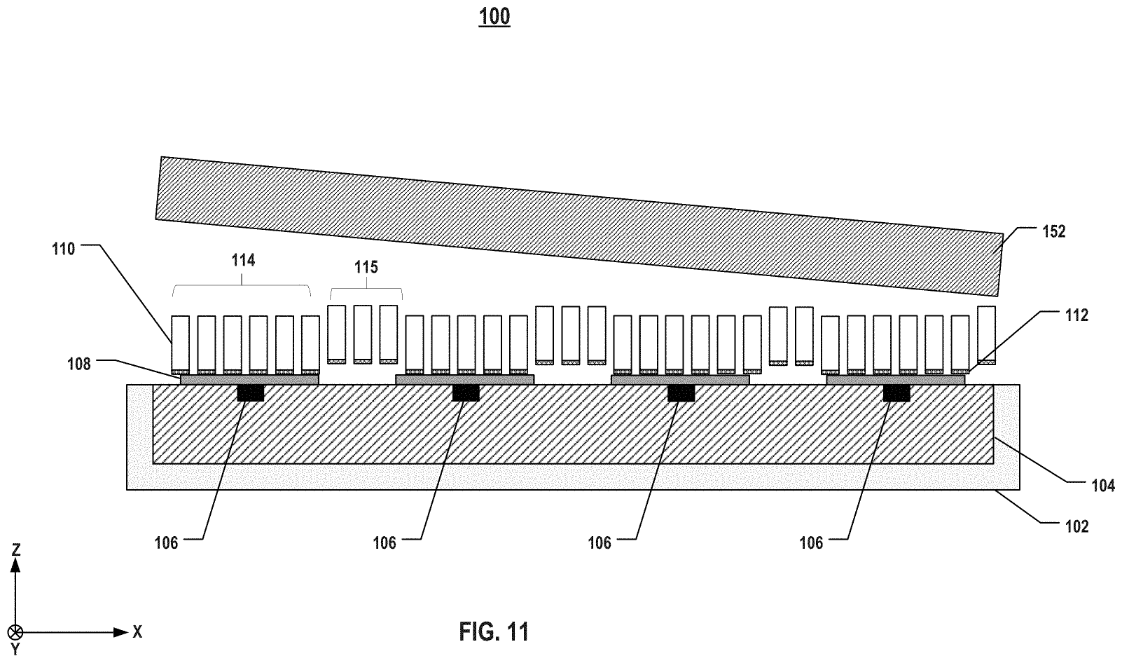

As shown in FIG. 11 and operation 510 of FIG. 13, substrate 152 is bonded to substrate 102 in a face-to-face manner. As described above, the size of LED units 110 is much less than the size of conductive pads 108, therefore, the alignment may not be needed during the bonding operation. In some implementations, only coarse alignment is needed. Furthermore, as shown in FIG. 11, a plurality of LED sets 114 of LED units 110 are in contact with conductive pads 108, and a plurality of LED sets 115, including a plurality of dummy LED units, are not in contact with any conductive pad.

Because each LED set 114 may include multiple LED units 110, when misalignment of the bonding process, most LED units 110 of LED set 114 may be still bonded on and in electric contact with conductive pad 108. Those bonded LED units 110 can be turned on/off by LED driving circuit through contacts 106 and conductive pads 108 despite the un-bonded LED units cannot. Therefore, the misalignment within a certain range will not cause the defect of the pixel points.

As shown in FIG. 11 and operation 512 of FIG. 13, substrate 152 is removed. In some implementations, substrate 152 may be removed by dry etch, wet etch, mechanical polishing, laser lift-off, or other suitable processes. In some implementations, the plurality of LED sets 115 that are not in contact with any conductive pad may be removed with substrate 152 as well. In some implementations, the plurality of LED sets 11$ that are not in contact with any conductive pad may be removed in a separate process.

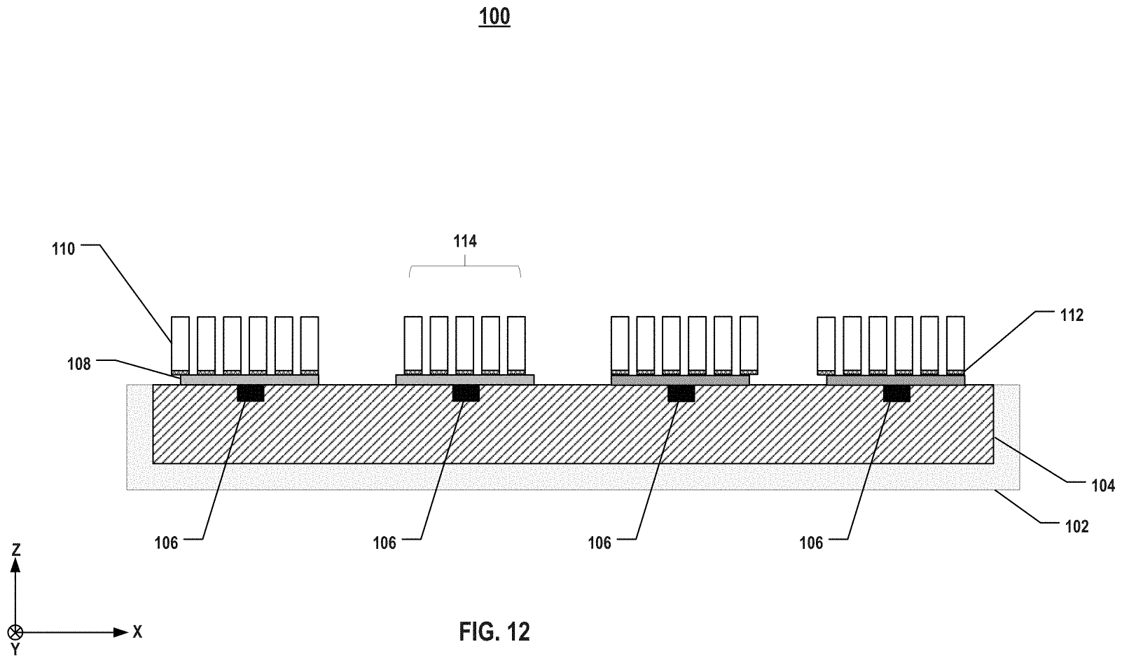

FIG. 12 shows the final structure of LED structure 100. LED driving circuit 104 is formed in substrate 102, and LED driving circuit 104 includes contacts 106. Conductive pads 108 are formed on LED driving circuit 104, and each conductive pad 108 is disposed on a corresponding contact 106. Each LED set 114 includes a plurality of LED units 110 disposed on one conductive pad 108. The plurality of LED units 110 of LED set 114 are in electric contact with one corresponding contact 106 through one conductive pad 108.

By using the structures and manufacturing processes described above, the bonding process of the LED structure does not need a fine alignment or does not even have to be aligned. Therefore, the manufacturing process may be simplified, and the manufacturing cost may be also lowered.

According to one aspect of the present disclosure, a LED structure is disclosed. The LED structure includes a substrate, a LED driving circuit, a plurality of conductive pads, and a first LED set. The LED driving circuit is formed in the substrate, and the LED driving circuit includes a plurality of contacts. The plurality of conductive pads are formed on the LED driving circuit, and each conductive pad of the plurality of conductive pads is disposed on a corresponding contact of the plurality of contacts. The first LED set includes a plurality of LED units disposed on a first conductive pad of the plurality of conductive pads. The plurality of LED units of the first LED set are in electric contact with the corresponding contact through the first conductive pad.

In some implementations, two adjacent contacts of the plurality of contacts are formed apart a first distance in the LED driving circuit, Two adjacent LED units in the plurality of LED units of the first LED set are separated on the first conductive pad by a first gap having a first width. The first distance is larger than the first width.

In some implementations, the LED structure further includes a second LED set adjacent to the first LED set. The second LED set includes a plurality of LED units disposed on a second conductive pad of the plurality of conductive pads adjacent to the first conductive pad. The first LED set and the second LED set are formed apart a second distance. The second distance is larger than the first width and smaller than the first distance.

in some implementations, cathodes of the plurality of LED units of the first LED set and cathodes of the plurality of LED units of the second LED set are in electric contact with each other, In some implementations, each LED unit of the first LED set further includes a conductive layer in electric contact with an anode of the LED unit, and the LED unit is disposed on the first conductive pad through the conductive layer. In some implementations, the plurality of LED units of the first LED set are separated by an isolation material formed through implantation.

According to another aspect of the present disclosure, a LED structure is disclosed. The LED structure includes a first semiconductor structure and a second semiconductor structure disposed on the first semiconductor structure. The first semiconductor structure includes a substrate, a LED driving circuit, and a plurality of conductive pads. The LED driving circuit is formed in the substrate, and the LED driving circuit includes a plurality of contacts. The plurality of conductive pads are formed on the LED driving circuit, and each conductive pad of the plurality of conductive pads is disposed on a corresponding contact of the plurality of contacts. The second semiconductor structure includes a plurality of active LED sets and a plurality of dummy LED sets. Each active LED set includes a plurality of active LED units disposed on a corresponding conductive pad. Each dummy LED set comprising a plurality of dummy LED units not disposed on any conductive pad, Cathodes of the plurality of active LED units and cathodes of the plurality of dummy LED units are in electric contact with each other.

In some implementations, cathodes of the plurality of active LED units and cathodes of the plurality of dummy LED units are in physical contact with each other. In some implementations, anodes of the plurality of active LED units are in electric contact with the corresponding conductive pad. In some implementations, anodes of the plurality of active LED units are in electric contact with the corresponding conductive pad through a conductive layer.

In some implementations, two adjacent contacts of the plurality of contacts are formed apart a first distance in the LED driving circuit. Two adjacent active LED units in the plurality of active LED units of each active LED set are separated on the corresponding conductive pad by a first gap having a first width. The first distance is larger than the first width.

In some implementations, two adjacent active LED sets of the plurality of active LED sets are formed apart a second distance. The second distance is larger than the first width and smaller than the first distance.

In some implementations, the plurality active LED units are separated by an isolation material formed through implantation.

According to a further aspect of the present disclosure, a method for manufacturing a LED structure is disclosed. A LED driving circuit is formed in a first substrate, and the LED driving circuit includes a plurality of contacts. A first semiconductor layer is formed on a second substrate. A plurality of conductive pads are formed on the plurality of contacts respectively. A plurality of LED units are formed in the first semiconductor layer. The second substrate is bonded to the first substrate, and a first set of LED units among the plurality of LED units is in contact with one conductive pad of the plurality of conductive pads, and a. second set of LED units among the plurality of LED units is not in contact with any conductive pad. The second substrate is removed.

In some implementations, a. second doping semiconductor layer is formed on the second substrate, a multiple quantum well (MQW) layer is formed on the second doping semiconductor layer, a first doping semiconductor layer is formed on the MQW layer, and the first doping semiconductor layer, the MQW layer, and the second doping semiconductor layer are divided to form the plurality of LED units.

In some implementations, an etch operation is performed to remove a portion of the first doping semiconductor layer, the MQW layer, and the second doping semiconductor layer to form the plurality of LED units. Two adjacent LED units in the plurality of LED units are separated by a first gap formed by the etch operation.

In some implementations, an implantation operation is performed to form an ion-implanted material in the first doping semiconductor layer. In some implementations, the second substrate having the plurality of LED units is bonded to the first substrate having the plurality of conductive pads in a face-to-face manner.

In some implementations, a plurality of conductive layers are formed on the plurality of LED units respectively, and the plurality of conductive layers are bonded onto the plurality of conductive pads. In some implementations, the second substrate is removed with an etch operation, a mechanical polishing operation, or a laser lift-off operation.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A light emitting diode (LED) structure, comprising:
a substrate;
a LED driving circuit formed in the substrate, the LED driving circuit comprising a plurality of contacts;
a plurality of conductive pads formed on the LED driving circuit, wherein each conductive pad of the plurality of conductive pads is disposed on a corresponding contact of the plurality of contacts; and
a first LED set comprising a plurality of LED units disposed on a first conductive pad of the plurality of conductive pads, wherein the plurality of LED units of the first LED set are in electric contact with the corresponding contact through the first conductive pad.

2. The LED structure of claim 1, wherein the LED structure further comprises a second LED set adjacent to the first LED set, the second LED set comprising a plurality of LED units disposed on a second conductive pad of the plurality of conductive pads adjacent to the first conductive pad.
wherein two adjacent contacts of the plurality of contacts are formed apart a first distance in the LED driving circuit, two adjacent LED units in the plurality of LED units of the first LED set are separated on the first conductive pad by a first width, the first conductive pad and the second conductive pad are separated by a gap having a second distance, and the second distance is larger than the first width but smaller than the first distance.

3. The LED structure of claim 2, wherein anodes of the plurality of LED units of the first LED set are in electric contact with the corresponding contact through the first conductive pad.

4. The LED structure of claim 1, wherein each LED unit of the first LED set further comprises a conductive layer in electric contact with an anode of the LED unit, and the LED unit is disposed on the first conductive pad through the conductive layer.

5. The LED structure of claim 1, wherein the plurality of LED units of the first LED set are separated by an isolation material formed through implantation.

6. A light emitting diode (LED) structure, comprising:
a first semiconductor structure, comprising:
a substrate;
a LED driving circuit formed in the substrate, the LED driving circuit comprising a plurality of contacts; and
a plurality of conductive pads formed on the LED driving circuit, wherein each conductive pad of the plurality of conductive pads is disposed on a corresponding contact of the plurality of contacts; and
a second semiconductor structure disposed on the first semiconductor structure, the second semiconductor structure comprising:
a plurality of active LED sets, each active LED set comprising a plurality of active LED units disposed on a corresponding conductive pad; and
a plurality of dummy LED sets, each dummy LED set comprising a plurality of dummy LED units not disposed on any conductive pad.

7. The LED structure of claim 6, wherein cathodes of the plurality of active LED units and cathodes of the plurality of dummy LED units are in electric contact with each other.

8. The LED structure of claim 7. wherein anodes of the plurality of active LED units are in electric contact with the corresponding conductive pad.

9. The LED structure of claim 8, wherein anodes of the plurality of active LED units are in electric contact with the corresponding conductive pad through a conductive layer.

10. The LED structure of claim 6, wherein two adjacent contacts of the plurality of contacts are formed apart a first distance in the LED driving circuit, two adjacent active LED units in the plurality of active LED units of each active LED set are separated on the corresponding conductive pad by a first width, two adjacent conductive pads of the plurality of conductive pads are separated by a gap having a second distance, and the second distance is larger than the first width but smaller than the first distance.

11. The LED structure of claim 6, wherein the plurality of active LED units and the plurality of dummy LED units are separated by an isolation material formed through implantation.

12. A method for manufacturing a light emitting diode (LED) structure, comprising:
forming a LED driving circuit in a first substrate, the LED driving circuit comprising a plurality of contacts;
forming a first semiconductor layer on a second substrate;
forming a plurality of conductive pads on the plurality of contacts respectively;
forming a plurality of LED units in the first semiconductor layer;
bonding the second substrate to the first substrate, wherein a first LED set of LED units among the plurality of LED units is in contact with one conductive pad of the plurality of conductive pads, and a second LED set of LED units among the plurality of LED units is not in contact with any conductive pad; and
removing the second substrate.

13. The method of claim 12, wherein forming the plurality of LED units in the first semiconductor layer further comprises:
forming a second doping semiconductor layer on the second substrate;
forming a multiple quantum well (MQW) layer on the second doping semiconductor layer;
forming a first doping semiconductor layer on the MQW layer; and
dividing the first doping semiconductor layer, the MQW layer, and the second doping semiconductor layer to form the plurality of LED units.

14. The method of claim 13, wherein dividing the first doping semiconductor layer, the MQW layer, and the second doping semiconductor layer to form the plurality of LED units further comprises:
performing an etch operation to remove a portion of the first doping semiconductor layer, the MQW layer, and the second doping semiconductor layer to form the plurality of LED units,
wherein two adjacent LED units in the plurality of LED units are separated by a first gap formed by the etch operation.

15. The method of claim 13, wherein dividing the first doping semiconductor layer, the MQW layer, and the second doping semiconductor layer to form the plurality of LED units, further comprises:
performing an implantation operation to form an ion-implanted material in the first doping semiconductor layer.

16. The method of claim 12, wherein bonding the second substrate to the first substrate further comprises:
bonding the second substrate having the plurality of LED units to the first substrate having the plurality of conductive pads in a face-to-face manner.

17. The method of claim 16, further comprising:
forming a plurality of conductive layers on the plurality of LED units respectively and
bonding the plurality of conductive layers onto the plurality of conductive pads.

18. The method of claim 12, wherein removing the second substrate further comprises:
removing the second substrate with an etch operation, a mechanical polishing operation, or a laser lift-off operation.

19. The method of claim 12. wherein removing the second substrate further comprises:
removing the second LED set of LED units.

20. The method of claim 12, wherein two adjacent contacts of the plurality of contacts are formed apart a first distance in the LED driving circuit, two adjacent LED units in the plurality of LED units of the first LED set are separated on the conductive pad by a first width, two adjacent conductive pads of the plurality of conductive pads are separated by a gap having a second distance, and the second distance is larger than the first width but smaller than the first distance.
